(19) United States
(12) Patent Application Publication
(10) Pub. No.: US 2016/0013241 A1
(43) Pub. Date: Jan. 14, 2016

(54) SEMICONDUCTOR DEVICE AND METHOD OF MANUFACTURING SAME

(71) Applicant: Renesas Electronics Corporation, Kawasaki-shi (JP)

(72) Inventor: Tadashi YAMAGUCHI, Kanagawa (JP)

(73) Assignee: Renesas Electronics Corporation, Kawasaki-shi (JP)

(21) Appl. No.: 14/747,019

(22) Filed: Jun. 23, 2015

(30) Foreign Application Priority Data
Jul. 9, 2014 (JP) 2014-141377

(51) Int. Cl. H01L 27/146

(52) U.S. Cl. CPC H01L 27/14645; H01L 27/14612; H01L 27/14621; H01L 27/14623; H01L 27/14627; H01L 27/14685; H01L 27/14689; H01L 27/14636; H01L 27/14625

(57) ABSTRACT

To provide a semiconductor device having improved performance.

A semiconductor substrate has an element formation surface, a light receiving surface opposite thereto, a transfer transistor formed on the side of the element formation surface, a photodiode coupled in series with the transfer transistor, and a wiring formed on the element formation surface. The semiconductor substrate has, on the light receiving surface thereof, a second insulating film which is a reaction film obtained by the reaction between a first amorphous insulating film and the semiconductor substrate made of silicon. Due to holes trapped in the interface states of the second insulating film, an inversion layer is formed on the light receiving side of the semiconductor substrate. It contributes to reduction in dark current noise caused by electrons generated at the crystal defects on the light receiving surface of the semiconductor substrate or in the vicinity thereof.

### CROSS-REFERENCE TO RELATED APPLICATIONS

The disclosure of Japanese Patent Application No. 2014-141377 filed on Jul. 9, 2014 including the specification, drawings, and abstract is incorporated herein by reference in its entirety.

### BACKGROUND

The present invention relates to a semiconductor device and a method of manufacturing same. It is suited for use, for example, in a semiconductor device including a solid state image sensor and a method of manufacturing same.

As a solid state image sensor, that (CMOS image sensor) using a CMOS (complementary metal oxide semiconductor) is being developed. This CMOS image sensor is comprised of a plurality of pixels each having a photodiode and a transfer transistor.

Japanese Patent No. 4798130 (Patent Document 1) discloses an invention relating to noise reduction of a solid state image sensor comprised of a CMOS image sensor. In particular, noise due to a dark current generated from interface states at the interface between a light receiving portion and an upper layer film is suppressed by a buried photodiode structure called “HAD (hole accumulation diode) structure”.

The paragraph (0018) of Patent Document 1 has the following description: a method of manufacturing a solid state image sensor includes a step of forming a silicon oxide film on a semiconductor substrate having thereon the light receiving portion and a step of forming a film having negative fixed charges on the silicon oxide film, wherein the film having negative fixed charges contributes to formation of a hole accumulation layer on the side of a light receiving surface of the light receiving portion.

Further, the paragraph (0019) has the following description: in the method of manufacturing a solid state image sensor, the film having negative fixed charges is formed on the silicon oxide film so that the hole accumulation layer is formed sufficiently at the interface on the side of the light receiving surface of the light receiving portion due to an electric field attributable to the negative fixed charges. Therefore, generation of charges (electrons) from the interface is suppressed. At the same time, even if charges (electrons) are generated, the charges flow in the hole accumulation layer having therein a large number of holes without causing them to flow into a charge storage portion that forms a potential well in the light receiving section and as a result, they can be eliminated. It is therefore possible to prevent a dark current generated by charges attributable to the interface from being detected at the light receiving portion and suppress the dark current due to interface states. Further, since the light receiving portion has, on the light receiving surface thereof, the silicon oxide film, generation of electrons due to interface states can be suppressed further, making it possible to suppress the electrons due to the interface states from flowing into the light receiving portion as a dark current.

Japanese Patent No. 4821917 (Patent Document 2), Japanese Patent No. 4821918 (Patent Document 3), and Japanese Patent No. 5151375 (Patent Document 4) disclose inventions, respectively, relating to the invention disclosed in Japanese Patent No. 4798130 (Patent Document 1).

Japanese Patent No. 4821917 (Patent Document 2) discloses a solid state image sensor having an insulating film between a film having negative fixed charges and the surface of a peripheral circuit portion.

Japanese Patent No. 4821918 (Patent Document 3) discloses a back-illuminated solid state image sensor having a hole accumulation layer formed from a film having negative fixed charges.

Japanese Patent No. 5151375 (Patent Document 4) discloses a solid state image sensor having, on a peripheral circuit portion thereof, a shielding film via a film having negative fixed charges.

### PATENT DOCUMENTS

[Patent Document 1] Japanese Patent No. 4798130
[Patent Document 2] Japanese Patent No. 4821917
[Patent Document 3] Japanese Patent No. 4821918
[Patent Document 4] Japanese Patent No. 5151375

### SUMMARY

There is a demand for providing a photodiode-having semiconductor device having improved performance, for example, having less noise which arises from a dark current.

Another problem and novel features will be apparent from the description herein and accompanying drawings.

According to one embodiment, a semiconductor substrate has, on the back surface thereof, a reaction film obtained by the reaction between a first amorphous insulating film and a silicon semiconductor substrate. This reaction film is a second amorphous insulating film and due to holes trapped in the interface state with the semiconductor substrate, an inversion layer is formed on the back surface side of the semiconductor substrate. The inversion layer formed on the back surface side of the semiconductor substrate contributes to reduction in dark current noise caused by electrons generated at the crystal defects on the back surface of the semiconductor substrate or in the vicinity of the back surface.

By the one embodiment, a semiconductor device having improved performance can be provided.

### BRIEF DESCRIPTION OF THE DRAWINGS

FIG. 1 is a fragmentary cross-sectional view of a semiconductor device of First Embodiment;

FIG. 2 is a fragmentary cross-sectional view of the semiconductor device of First embodiment during a manufacturing step thereof;

FIG. 3 is a fragmentary cross-sectional view of the semiconductor device during a manufacturing step following that of FIG. 2;

FIG. 4 is a fragmentary cross-sectional view of the semiconductor device during a manufacturing step following that of FIG. 3;

FIG. 5 is a fragmentary cross-sectional view of a semiconductor device for describing the advantage of the semiconductor device of First Embodiment;

FIG. 6 is a fragmentary cross-sectional view of a semiconductor device of Second Embodiment; and

FIG. 7 is a fragmentary cross-sectional view of a semiconductor device of Third Embodiment.

### DETAILED DESCRIPTION

In the following embodiments, a description may be made after divided in a plurality of sections or embodiments if necessary for the sake of convenience. These sections or embodiments are not independent from each other unless otherwise particularly specified, but one of them may be a modification example, detailed description, complementary description, or the like of a part or whole of the other one. In the following embodiments, when a reference is made to the number of a component (including the number, value, amount, range, or the like), the number is not limited to a specific number but may be more or less than the specific number, unless otherwise particularly specified or principally apparent that the number is limited to the specific number. Further, in the following embodiments, it is needless to say that the constituent component (including component step or the like) is not always essential unless otherwise particularly specified or principally apparent that it is essential. Similarly, in the following embodiments, when a reference is made to the shape, positional relationship, or the like of the constituent component, that substantially approximate or analogous to it is also embraced unless otherwise particularly specified or principally apparent that it is not. This also applies to the above-mentioned number, range, or the like.

Embodiments will hereinafter be described in detail based on drawings. In all the drawings for describing the embodiments, members having the same function will be identified by the same reference numerals and overlapping descriptions will be omitted. In the following embodiments, a description on the same or similar portion is not repeated in principle unless otherwise particularly necessary.

In the drawings to be used in the following embodiments, even a cross-sectional view is sometimes not hatched to facilitate understanding of it. On the other hand, even a plan view is sometimes hatched to facilitate understanding of it.

### First Embodiment

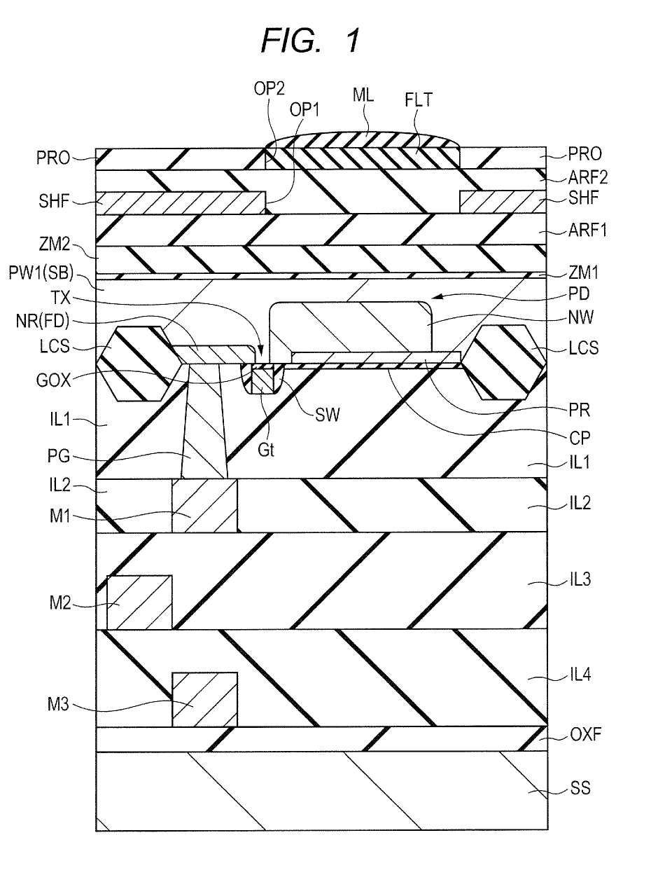

The structure and manufacturing steps of a semiconductor device of First Embodiment will hereinafter be described referring to drawings. The semiconductor device of First Embodiment is a back-illuminated CMOS image sensor in which light is made incident from the back surface side of a semiconductor substrate.

<Constitution of semiconductor device> FIG. 1 is a fragmentary cross-sectional view of the semiconductor device of the present embodiment. The CMOS image sensor has a plurality of pixels and each pixel includes a photodiode PD and a transfer transistor TX coupled in series. FIG. 1 shows a photodiode PD and a transfer transistor TX included in a single pixel. In the present embodiment, a combination example of a pnp type photodiode PD and an n channel type transfer transistor TX will be described, but a combination of an npn type photodiode and a p channel type transfer transistor may also be used.

As shown in FIG. 1, a semiconductor substrate SB has thereon a photodiode PD and a transfer transistor TX. The photodiode PD is comprised of a p type well PW1, an n type semiconductor region (n type well) NW, and a p⁺ type semiconductor region PR, each formed in the semiconductor substrate SB. As shown in FIG. 1, in a region having the photodiode PD and the transfer transistor TX therein, the p type well PW1 and the semiconductor substrate SB are the same region. The semiconductor substrate SB has a main surface and a back surface. On the side of the main surface, it has the photodiode PD and the transfer transistor TX. The photodiode PD and the transfer transistor TX have thereon a plurality of wiring layers. On the back surface side, light is incident on the photodiode PD. Therefore, the main surface of the semiconductor substrate SB can be called “element formation surface”, while the back surface can be called “light incident surface, light receiving surface”. FIG. 1 shows the element formation surface of the semiconductor substrate SB to be on the lower side and the light incident surface to be on the upper side. The terms relating to a direction such as “upper” “lower”, “depth”, or “thickness”, used in a description on portions shown on the side lower than the semiconductor substrate SB therefore mean a position or direction opposite to that shown in FIG. 1. For example, the depth shows a perpendicularly upward direction in FIG. 1 and the thickness shows a perpendicularly downward direction in FIG. 1.

The semiconductor substrate SB is a semiconductor substrate (semiconductor wafer) made of, for example, single crystal silicon. As another mode, the semiconductor substrate SB may be a so-called epitaxial wafer. When the semiconductor wafer SB is an epitaxial wafer, the semiconductor substrate SB can be formed, for example, by causing an epitaxial layer composed of single crystal silicon to grow on the main surface of a single crystal silicon substrate. The epitaxial wafer has a stacked structure of a single crystal silicon substrate and an epitaxial layer composed of single crystal silicon. When the epitaxial wafer is used, the photodiode PD and the transfer transistor TX are formed in the epitaxial layer.

The semiconductor substrate SB has, in the main surface thereof, an element isolation region LCS made of an insulator. Although not illustrated here, it encompasses, in plan view, formation regions of the photodiode PD and the transistor TX.

The semiconductor substrate SB has, from the main surface to the back surface thereof, a p type well (p type semiconductor region) PW1. The p type well PW1 extends over the formation region of the photodiode PD and the formation region of the transfer transistor TX.

As shown in FIG. 1, the semiconductor substrate SB has, in the main surface thereof, an n type semiconductor region (n type well) NW which is formed so as to be embraced in the p type well PW1. The n type semiconductor region NW is an n type semiconductor region introduced with an n type impurity such as phosphorus (P) or arsenic (As).

The n type semiconductor region NW is an n type semiconductor region for forming the photodiode PD and it is, at the same time, a source region of the transfer transistor TX. The n type semiconductor region NW (bottom surface thereof) has a depth smaller than that of the p type well PW1 (bottom surface thereof).

The n type semiconductor region NW has, in a portion of the surface thereof (on the main surface side of the semiconductor substrate SB), a p⁺ type semiconductor region PR. The p⁺ type semiconductor region PR is a p⁺ type semiconductor region introduced (doped) heavily with a p type impurity such as boron (B). The impurity concentration (p type impurity concentration) of the p⁺ type semiconductor region PR is higher than the impurity concentration (p type impurity concentration) of the p type well PW1. The p⁺ type semiconductor region PR has a conductivity (electric conductivity) higher than a conductivity (electric conductivity) of the p type well PW1.

The depth of the p⁺ type semiconductor region PR (bottom surface thereof) is shallower than the depth of the n type semiconductor region NW (bottom surface thereof). The p⁺ type semiconductor region PR is formed mainly in a surface layer portion (surface portion) of the n type semiconductor region NW. When viewed in a thickness direction of the semiconductor substrate SB, therefore, the p⁺ type semiconductor region PR which is the uppermost layer has therebelow the n type semiconductor region NW and the n type semiconductor region NW has therebelow the p type well PW1.

In a region between the n type semiconductor region NW and the element isolation region LCS, the p⁺ type semiconductor region PR is partially contiguous to the p type well PW1. This means that the p⁺ type semiconductor region PR has a portion having immediately therebelow the n type semiconductor region NW and contiguous to the n type semiconductor region NW and a portion having immediately therebelow the p type well PW1 and contiguous to the p type well PW1.

The p type well PW1 and the n type semiconductor region NW have therebetween a PN junction. The p⁺ type semiconductor region PR and the n type semiconductor region NW have therebetween a PN junction. The p type well PW1 (p type semiconductor region), the n type semiconductor region NW, and the p⁺ type semiconductor region PR constitute a pnp type photodiode PD.

The p⁺ type semiconductor region PR serves to suppress electrons from being generated due to interface states formed in the main surface of the semiconductor substrate SB. Described specifically, in a surface region of the semiconductor substrate SB, electrons may be generated by the influence of interface states and cause an increase in dark current even when no light is irradiated. By forming a p⁺ type semiconductor region PR in which holes are majority carriers in the surface of the n type semiconductor region NW in which electrons are as majority carriers, it is possible to suppress formation of electrons and thereby suppress an increase in dark current under the light irradiation free situation. The p⁺ type semiconductor region PR therefore has a role of recombining electrons springing up from the outermost surface of the photodiode with the holes of the p⁺ type semiconductor region PR and thereby decreasing a dark current.

The photodiode PD is a light receiving element. The photodiode PD can also be regarded as a photoelectric conversion element. The photodiode PD has a function of forming charges through photoelectric conversion of an input light and accumulating the resulting charges, while the transfer transistor TX has a role as a switch in transferring, from the photodiode PD, the charges accumulated in the photodiode PD.

A gate electrode Gt planarly overlaps with a portion of the n type semiconductor region NW. This gate electrode Gt is a gate electrode of the transfer transistor TX and formed (placed) on the semiconductor substrate SB via a gate insulating film GOX. The gate electrode Gt has, on the sidewall thereof, a sidewall spacer SW as a sidewall insulating film.

In the semiconductor substrate SB (p type well PW1), the gate electrode Gt has, on one side of two sides thereof, the n type semiconductor region NW and has, on the other side, an n type semiconductor region NR. The n type semiconductor region NR is an n⁺ type semiconductor region introduced (doped) heavily with an n type impurity such as phosphorus (P) or arsenic (As) and lies in the p type well PW1. The n type semiconductor region NR is a semiconductor region as a floating diffusion (floating diffusion layer) FD and it is also a drain region of the transfer transistor TX.

The n type semiconductor region NW is a constituent of the photodiode PD, but can function as a semiconductor region for a source of the transfer transistor TX. This means that a source region of the transfer transistor TX is comprised of the n type semiconductor region NW. The n type semiconductor region NW and the gate electrode Gt are therefore positioned so that a portion (on the source side) of the gate electrode Gt planarly (in plan view) overlaps with a portion of the n type semiconductor region NW. The n type semiconductor region NW and the n type semiconductor region NR are formed so as to be separated from each other with a channel formation region of the transfer transistor TX (corresponding to a substrate region immediately below the gate electrode Gt) therebetween.

The photodiode PD has, on the surface thereof, that is, on the surface (main surface of the semiconductor substrate SB) of the n type semiconductor region NW and the p⁺ type semiconductor region PR, a cap insulating film CP. This cap insulating film CP serves to keep good surface properties, that is, good interface properties of the semiconductor substrate SB.

The semiconductor substrate SB has thereon an interlayer insulating film IL1 which is formed so as to cover the gate electrode Gt. The interlayer insulating film IL1 is made of a silicon oxide film using, for example, TEOS (tetra ethyl ortho silicate) as a raw material. The interlayer insulating film IL1 has therein a conductive plug PG. For example, as shown in FIG. 1, the n type semiconductor region NR as a floating diffusion FD has thereon the plug PG and this plug PG penetrates through the interlayer insulating film IL1 and reaches the n type semiconductor region NR. It is electrically coupled to the n type semiconductor region NR.

The conductive plug PG is formed by filling a contact hole formed in the interlayer insulating film IL1 with, for example, a barrier conductor film and a tungsten film formed on the barrier conductor film. The barrier conductor film is made of, for example, a stacked film (meaning, a titanium/titanium nitride film) of a titanium film and a titanium nitride film formed thereon.

The interlayer insulating film IL1 filled with the plug PG has thereon, for example, an interlayer insulating film IL2 and this interlayer insulating film IL2 has therein a wiring M1.

The interlayer insulating film IL2 is made of, for example, a silicon oxide film. Not only it, but also a low dielectric constant film having a dielectric constant lower than that of the silicon oxide film can be used. Examples of the low dielectric constant film include an SiOC film.

The wiring M1 is made of, for example, a copper wiring and it can be formed by the damascene process. The wiring M1 is not limited to the copper wiring and an aluminum wiring may also be used. When the wiring M1 is a buried copper wiring (damascene copper wiring), the buried copper wiring is formed in a wiring trench formed in the interlayer insulating film IL1. When the wiring M1 is an aluminum wiring, the aluminum wiring is formed by patterning a conductive film formed on the interlayer insulating film IL1. The wiring M1 is formed on the gate electrode Gt of the transfer transistor TX so that the gate electrode Gt lies between the element formation surface of the semiconductor substrate SB and the wiring M1.

The interlayer insulating film IL2 having therein the wiring M1 has thereon, for example, an interlayer insulating film IL3 made of a silicon oxide film or a low dielectric constant film and this interlayer insulating film IL3 has therein a wiring M2. The interlayer insulating film IL3 having therein the wiring M2 has thereon an interlayer insulating film IL4 and this interlayer insulating film IL4 has therein a wiring M3. The wirings M1 to M3 constitute a wiring layer.

The interlayer insulating film (IL4) has thereon a support substrate SS via an adhesive film OXF made of a silicon oxide film.

As shown in FIG. 1, the semiconductor substrate SB has, on the back surface thereof, an insulating film ZM, an anti-reflective film ARF1, a shielding film SHF, an anti-reflective film ARF2, a protective film PRO, a color filter FLT, and a microlens ML. In the description on these portions, terms relating to a direction such as upper, lower, depth, or thickness mean a direction shown in FIG. 1.

The semiconductor substrate SB has, on the back surface thereof (in other words, the bottom surface, light receiving surface, or light incident surface of the p type well PW1), an insulating film ZM1 and this insulating film ZM1 has thereon an insulating film ZM2. The insulating film ZM2 is an amorphous insulating film of HfₓO_{y}, TaₓO_{y}, AlₓO_{y}, ZrₓO_{y}, or TiₓO_{y} (in any case, x+y=1). As will be described later in the description on a manufacturing method, the insulating film ZM1 is a reaction film obtained by the reaction between the insulating film ZM2 and the semiconductor substrate SB (p type well PW1). The insulating film ZM1 corresponds to the amorphous insulating film used as the insulating film ZM2 and becomes Hf_{α}Si_{β}O_{χ}, Ta_{α}Si_{β}O_{χ}, Al_{α}Si_{β}O_{χ}, or Ti_{α}Si_{β}O_{χ} (in any case, α+β+χ=1). The insulating film ZM2 is formed as an amorphous insulating film by PVD (physical vapor deposition) to have a thickness of from 20 nm to 50 nm. The insulating film ZM1 is also an amorphous insulating film and has a thickness of from 2 nm or less.

The insulating film ZM1 and the insulating film ZM2 cover at least the formation region of the photodiode PD in plan view. Further, it covers the formation regions of the photodiode PD and the transfer transistor TX, that is, a region encompassed by the element isolation region LCS as shown in FIG. 1.

The insulating film ZM2 has thereon an anti-reflective film ARF1 which is made of, for example, a silicon oxide film and covers the insulating film ZM2.

The anti-reflective film ARF1 has thereon a shielding film SHF which is made of, for example, an aluminum film and covers the anti-reflective film ARF1. The shielding film SHF has an opening OP1 corresponding to the formation region of the photodiode PD.

The shielding film SHF has thereon an anti-reflective film ARF2 which is made of, for example, a silicon oxide film and covers the shielding film SHF. The opening OP1 of the shielding film SHF is filled with the anti-reflective film ARF2.

The anti-reflective film ARF2 has thereon a protective film PRO made of, for example, a silicon nitride film. The protective film PRO has an opening OP2 corresponding to the formation region of the photodiode PD. The opening OP2 provided in the protective film PRO overlaps, in plan view, with the opening OP1 provided in the shielding film SHF.

The protective film PRO has, in the opening OP2 thereof, a color filter FLT and the color filter FLT has thereon a microlens ML.

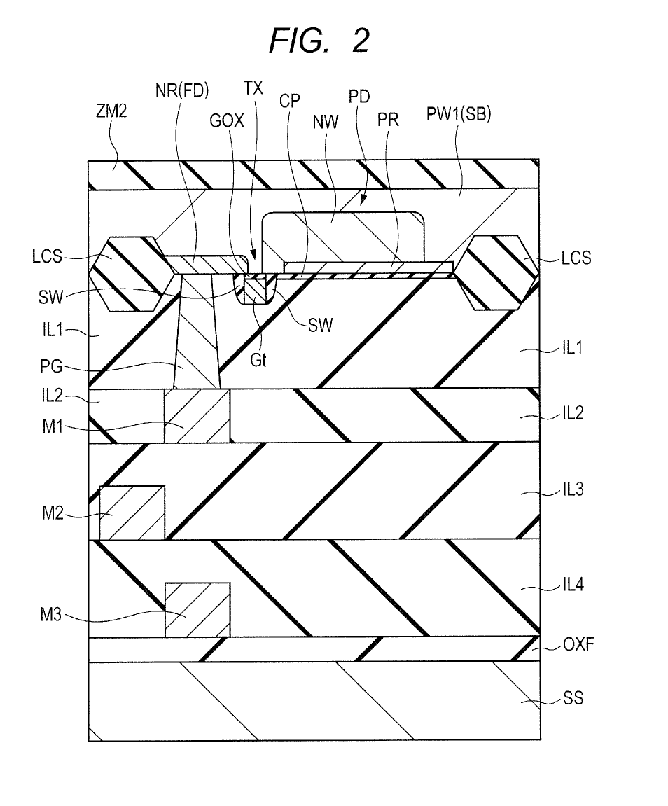

Light incident from the microlens ML is narrowed by a color filter FLT to light having a desired wavelength, that is, red, green, or blue light. It passes through the anti-reflective films ARF2 and ARF1, the insulating film ZM2, and the insulating film ZM1 and taken in the photodiode PD.

<Manufacturing method of semiconductor device> Next, a method of manufacturing the semiconductor device of the present embodiment will be described referring to FIGS. 2 to 4 and FIG. 1. FIGS. 2 to 4 are fragmentary cross-sectional views of the semiconductor device of the present embodiment during manufacturing steps.

First, provided is a semiconductor substrate SB having an element formation surface, a light receiving surface, a transfer transistor TX formed on the side of the element formation surface, a photodiode PD coupled in series with the transfer transistor TX, and a wiring M1 formed on the element formation surface. The constitution of each of the transfer transistor TX, the photodiode PD, the wiring M1, and the like is as described above referring to FIG. 1.

FIG. 2 shows a step of forming an insulating film ZM2. The insulating film ZM2 is formed on the light receiving surface (back surface) of the semiconductor substrate SB so as to come into contact with the light receiving surface of the semiconductor substrate SB. The insulating film ZM2 comes into contact with single crystal silicon constituting the semiconductor substrate SB. The insulating film ZM2 is formed by PVD so as to obtain it as an amorphous insulating film. Since it is an amorphous insulating film, it has a large amount of interface states at the interface with the semiconductor substrate SB made of silicon.

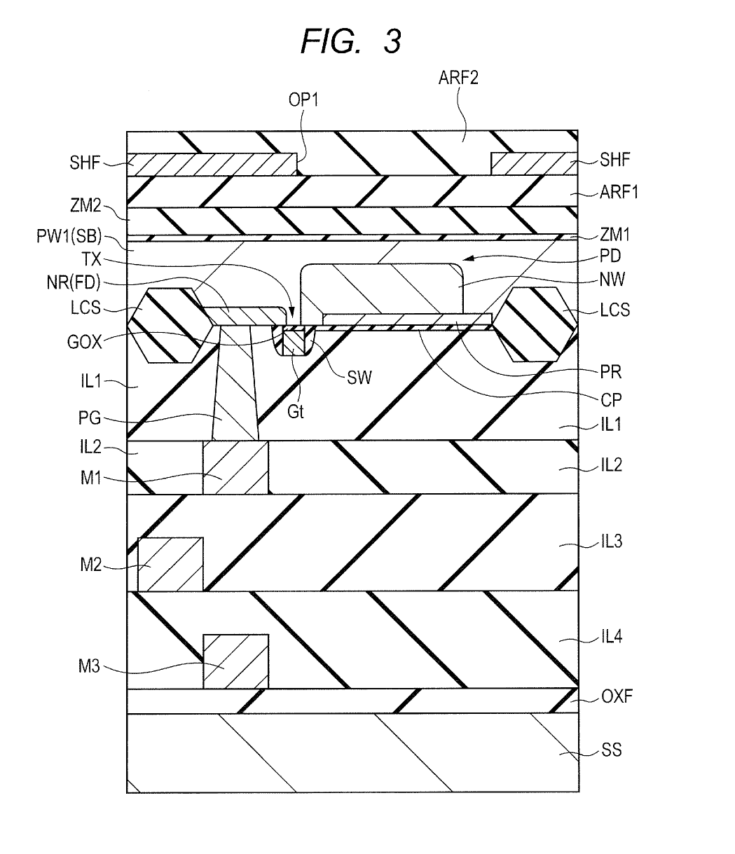

FIG. 3 shows a step of forming an anti-reflective film ARF1, a shielding film SHF, and an anti-reflective film ARF2. The anti-reflective film ARF1 is formed on the insulating film ZM2 so as to cover the insulating film ZM2. The anti-reflective film ARF1 is made of a silicon oxide film or the like and is formed by CVD (chemical vapor deposition), for example, plasma CVD under film forming conditions of 400° C. or less. Next, a shielding film SHF having an opening OP1 for exposing a formation region of the photodiode PD formed in the semiconductor substrate SB is formed on the anti-reflective film ARF1. The shielding film SHF is made of an aluminum film by PVD. After deposition of the aluminum film, with an unillustrated photoresist film having a desired pattern as a mask, the aluminum film is anisotropically etched to form the opening OP1. This anti-reflective film ARF1 also has a role of preventing the insulating film ZM2 from being etched in this anisotropic etching step.

Next, an anti-reflective film ARF2 is formed on the shielding film SHF having the opening OP1. The anti-reflective film ARF2 is made of a silicon oxide film or the like and is formed by plasma CVD under the film forming conditions of 400° C. or less. The anti-reflective films ARF1 and ARF2 are formed as a two-layer structure. For example, the anti-reflective film ARF1 can however be omitted. In this case, proper anisotropic etching conditions must be used in order to prevent the insulating film ZM2 from being etching during anisotropic etching of the shielding film SHF.

As shown in FIG. 3, in the plasma CVD step which is a formation step of one or both of the anti-reflective films ARF1 and ARF2, a heat load of from 250 to 400° C. is applied to the semiconductor substrate SB to form, as an insulating film ZM1, a reaction film obtained by the reaction between the semiconductor substrate SB made of silicon and the insulating film ZM2 which is an amorphous insulating film. As described above, the anti-reflective films ARF1 and ARF2 are formed by plasma CVD at a low temperature, the reaction film ZM1 is obtained as an amorphous insulating film without crystallization. The shielding film SHF is formed by PVD so that the temperature of the semiconductor substrate SB is, needless to say, 400° C. or less.

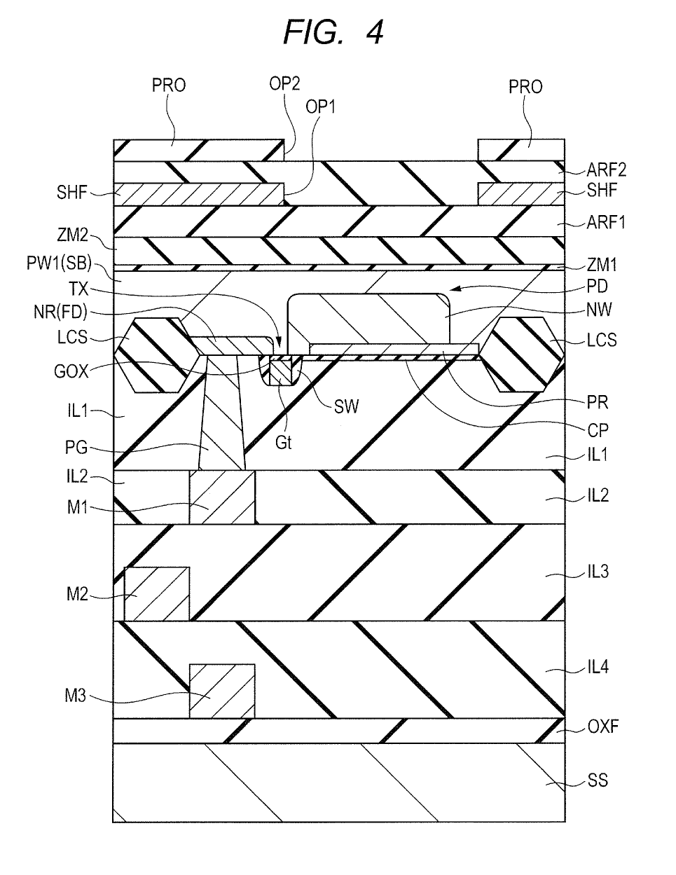

FIG. 4 shows a step of forming a protective film PRO. The protective film PRO is formed on the anti-reflective film ARF2. The protective film PRO is made of, for example, a silicon nitride film having high humidity resistance and mechanical strength and is formed by plasma CVD under the film forming conditions of 400° C. or less. In a manner similar to that employed for the formation of the opening OP1 in the shielding film SHF, an opening OP2 is formed in the protective film PRO. Next, as shown in FIG. 1, the opening OP2 of the protective film PRO is filled with a color filter FLT and a microlens ML.

The color filter FLT can be formed selectively, for example, by applying a pigment-containing photosensitive resin onto the protective film and then, carrying out an exposure step and a development step. The microlens ML can be formed, for example, by forming a phenolic photosensitive resin on the protective film PRO and the color filter FLT, leaving the photosensitive resin for the formation of the microlens ML selectively only on the upper portion of the color filter FLT by using conventional photolithography, and melting the photosensitive resin. Then, by surface tension, the microlens ML can be formed in a semi-spherical shape. The formation steps of the color filter FLT and the microlens ML are performed at 150° C. or less.

Even after formation of the protective film PRO, the color filter FLT, and the microlens ML, therefore, the insulating films ZM1 and ZM2 still remain as an amorphous insulating film.

By the above-mentioned steps, the semiconductor device of the present embodiment can be manufactured.

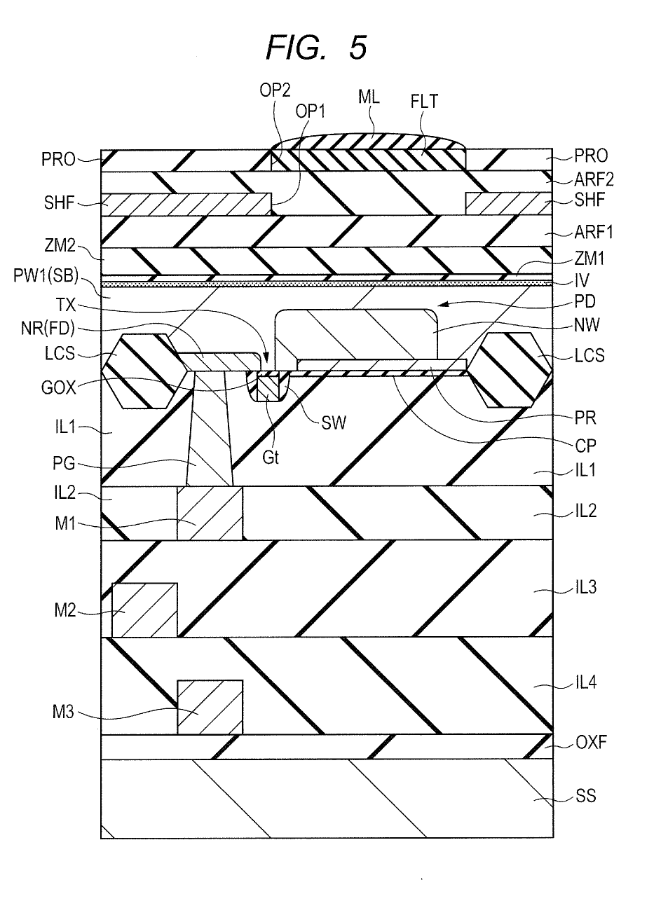

FIG. 5 is a fragmentary cross-sectional view of the semiconductor device for describing the advantage of the semiconductor device of the present embodiment. FIG. 5 has an inversion layer IV in addition to the constitution shown in FIG. 1. As is apparent from the above description, the semiconductor substrate SB on the side of the light receiving surface is the p type well PW1 which is a portion of the photodiode PD. The semiconductor substrate SB has, on the light receiving surface thereof, the insulating film ZM2, an amorphous insulating film. By a heat load during formation of the anti-reflective film ARF1 and the like, the light receiving surface of the semiconductor substrate SB and the insulating film ZM2 have therebetween the insulating film ZM1 which is a reaction film obtained by the reaction between silicon constituting the semiconductor substrate SB and the insulating film ZM2 as an amorphous insulating film. As described above, the insulating film ZM1 is also an amorphous insulating film and a large amount of interface states are present at the interface between the insulating film ZM1 and the semiconductor substrate SB. Holes which are majority carriers of the p type well PW1 are trapped in the above-mentioned interface states so that the insulating film ZM1 has positive charges. As shown in FIG. 5, the insulating film ZM1 has positive charges so that the semiconductor substrate SB has, on the side of the light receiving surface, the inversion layer IV. Presence of this inversion layer IV prevents electrons, which have been generated at the crystal defects on the light receiving surface of the semiconductor substrate SB or in the vicinity thereof, from crossing an energy barrier between the inversion layer IV and the p type well PW1 and thereby preventing them from flowing in the photodiode PD. This means that the insulating film ZM1, an amorphous insulating film, having a large amount of interface states is brought into contact with the light receiving surface of the semiconductor substrate SB so that dark current noise of the CMOS image sensor can be reduced. In other words, a semiconductor device with a CMOS image sensor having improved performance can be provided.

The semiconductor device of the present embodiment has been described above by using a combination example of the pnp type photodiode PD and the n channel type transfer transistor. A similar effect can be obtained from a combination example of an npn type photodiode and a p channel type transfer transistor. In this case, it is only necessary to reverse the conductivity type of the p type well PW1, the n type semiconductor region NW, the p⁺ type semiconductor region PR, and the n type semiconductor region NR. Described specifically, the semiconductor substrate SB has, on the side of the light receiving surface thereof, an n type well which is a portion of a photodiode PD. The semiconductor substrate SB has, on the light receiving surface thereof, an insulating film ZM2 which is an amorphous insulating film. By a heat load during formation of films such as an anti-reflective film ARF1, the light receiving surface of the semiconductor substrate SB and the insulating film ZM2 have therebetween an insulating film ZM1 which is a reaction film obtained by the reaction between silicon constituting the semiconductor substrate SB and the insulating film ZM2, an amorphous insulating film. The insulating film ZM1 is an amorphous insulating film and the insulating film ZM1 and the semiconductor substrate SB have, at an interface therebetween, a large amount of interface states. Electrons which are majority carriers of the n type well are trapped in the above-mentioned interface states and the insulating film ZM1 has negative charges. As shown in FIG. 5, the insulating film ZM1 has negative charges so that the semiconductor substrate SB has, on the side of the light receiving surface thereof, an inversion layer IV. Presence of this inversion layer IV prevents holes, which have been generated at the crystal defects on the light receiving surface of the semiconductor substrate SB and in the vicinity thereof, from crossing an energy barrier of the inversion layer and therefore entering the photodiode PD. This means that since the insulating film ZM1, an amorphous insulating film, having a large amount of interface states is brought into contact with the light receiving surface of the semiconductor substrate SB, dark current noise of the CMOS image sensor having an npn type photodiode and a p channel type transfer transistor can be reduced.

As described above, it is necessary to apply, to the insulating film ZM2 formed as an amorphous insulating film, heat treatment (heat load) of 250° or higher but not higher than 400° C. to form the insulating film ZM1 which is a reaction film. After formation of the insulating film ZM2 which is an amorphous insulating film, heat treatment (heat load) at high temperatures exceeding 400° C. should not be applied to the semiconductor substrate SB. Application of heat treatment at high temperatures exceeding 400° C. leads to reduction in interface states of the insulating film ZM1.

In Patent Document 1, detection of a dark current at the light receiving portion is prevented by providing a film having negative fixed charges on a semiconductor substrate via a silicon oxide film and thereby forming a hole accumulation layer in the surface of the semiconductor substrate. According to the study by the present inventors, a thick silicon oxide film should be formed in order to prevent a leakage current from the film having negative fixed charges to the semiconductor substrate, but there is a trade-off relationship. This means that an increase in the thickness makes it difficult to form a hole accumulation layer or requires an increases in an amount of negative fixed charges.

In the present embodiment, as described above, the formation mechanism of an inversion layer is different so that it is not necessary to consider a leakage current to the semiconductor substrate.

### Second Embodiment

Second Embodiment corresponds to a modification example of First Embodiment. A semiconductor device according to Second Embodiment does not have the insulating film ZM1 of First Embodiment which is a reaction film.

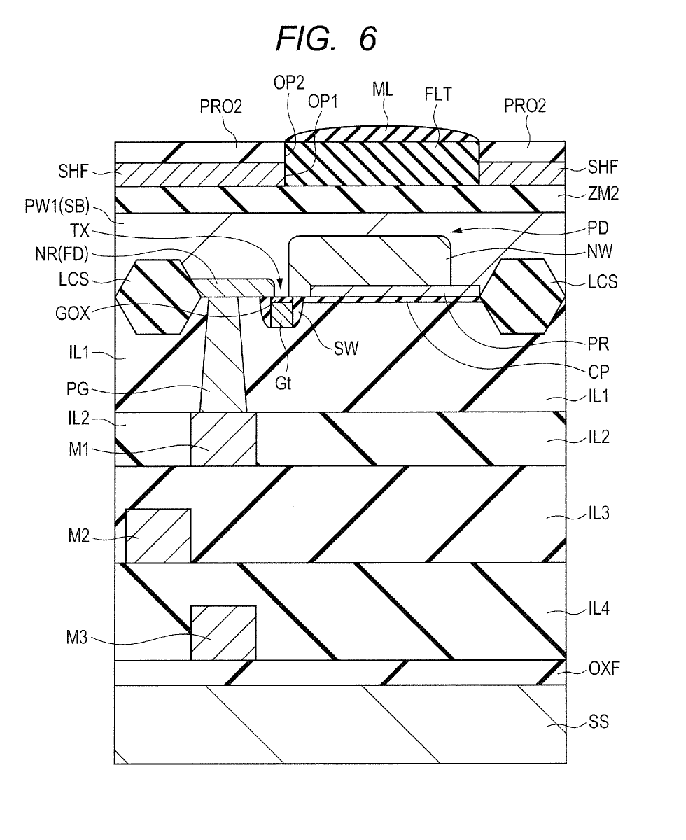

FIG. 6 is a fragmentary cross-sectional view of the semiconductor device of Second Embodiment. A portion of FIG. 6 lower than the semiconductor substrate SB is similar to that of First Embodiment. The semiconductor substrate SB has, on the side of a light receiving surface thereof, an insulating film ZM2, which is an amorphous insulating film, contiguous to the semiconductor substrate SB (p type well PW1). The manufacturing method and material of the insulating film ZM2 are similar to those used in First Embodiment.

The insulating film ZM2 has thereon a shielding film SHF having an opening OP1, which is similar to that of First Embodiment, and the shielding film SHF has thereon a protective film PRO2 having an opening OP2. The opening OP2 of the protective film PRO2 is placed so as to overlap with the opening OP1 of the shielding film SHF. The openings OP1 and OP2 have therein a color filter FLT and a microlens ML. The color filter FLT and the microlens ML are similar to those of First Embodiment. The protective film PRO2 is made of, for example, a photosensitive polyimide resin film.

Second Embodiment does not include a step of forming, after formation of the insulating film ZM2 which is an amorphous insulating film, an inorganic insulating film (silicon oxide film, silicon nitride film, or the like) which step requires application of a heat load of from 250° C. to 400° C. to the semiconductor substrate SB as performed in First Embodiment. Therefore, the insulating film ZM1 which is a reaction film obtained by the reaction between the insulating film ZM2, an amorphous insulating film, and the semiconductor substrate SB made of silicon is not formed.

The insulating film ZM2 which is an amorphous insulating film has a large amount of interface states at the interface with the semiconductor substrate SB so that as in First Embodiment, holes which are majority carriers of the p type well PW1 are trapped in the interface states of the insulating film ZM2 and the insulating film ZM2 has positive charges. Since the insulating film ZM2 has positive charges, an inversion layer IV is formed on the side of the light receiving surface of the semiconductor substrate SB. In short, in Second Embodiment, the insulating film ZM2 plays the role of the insulating film ZM1 in First Embodiment to reduce dark current noise of the CMOS image sensor.

Next, a method of manufacturing the semiconductor device of Second Embodiment will be described.

In a manner similar to that of First Embodiment, provided is a semiconductor substrate SB having an element formation surface, a light receiving surface, a transfer transistor TX formed on the side of the element formation surface, a photodiode PD coupled in series with the transfer transistor TX, and a wiring M1 formed on the element formation surface.

Next, an insulating film ZM2 is formed on the light receiving surface (back surface) of the semiconductor substrate SB so that it comes into contact with the light receiving surface of the semiconductor substrate SB. The insulating film ZM2 is formed by PVD so as to obtain it as an amorphous insulating film.

Next, after deposition of an aluminum film, which will be a shielding film SHF, on the insulating film ZM2 by PVD, the aluminum film is anisotropically etched with an unillustrated photoresist mask having a desired pattern as a mask. Thus, an opening OP1 can be formed.

Next, a protective film PRO2 made of, for example, a photosensitive polyimide resin film is formed on the shielding film SHF. By subjecting the photosensitive polyimide resin film to exposure and development treatment, the protective film PRO2 having an opening OP2 can be formed. In the step of forming the opening OP1 in the shielding film SHF, the opening OP1 can also be formed by forming an opening OP2 in the photosensitive polyimide resin film and then anisotropically etching the shielding film SHF with the resulting photosensitive polyimide resin film as a mask, without providing a mask made of a photoresist film for exclusive use.

Next, in a manner similar to that of First Embodiment, a color filter FLT and a microlens ML are formed in the openings OP1 and OP2 to complete the semiconductor device of Second Embodiment.

As described in First Embodiment, the step of forming the color filter FLT and the microlens ML is performed at 150° C. or less and the shielding film SHF is formed by PVD so that the semiconductor substrate SB is almost free from a heat load. The photosensitive polyimide resin film needs a curing annealing step after the development. Curing annealing is however performed at 200° C. or less so that the insulating film ZM1, which is a reaction film obtained by the reaction between the insulating film ZM2, an amorphous insulating film, and the semiconductor substrate SB made of silicon, is not formed in Second Embodiment.

### Third Embodiment

Third Embodiment corresponds to a modification example of Second Embodiment. A semiconductor device of Third Embodiment is similar to that of Second Embodiment except that it has an insulating film ZM1 which is a reaction film.

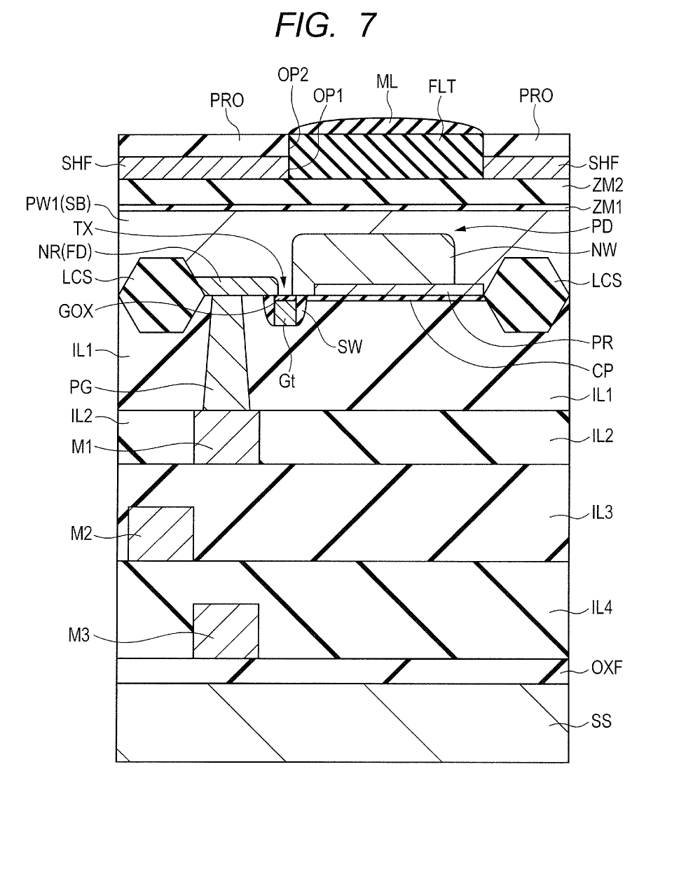

FIG. 7 is a fragmentary cross-sectional view of the semiconductor device of Third Embodiment. In the semiconductor device of Third Embodiment, the insulating film ZM1 is formed intentionally by adding a heat treatment step to the manufacturing method of the semiconductor device of Second Embodiment. Described specifically, after formation of the insulating film ZM2 which is an amorphous insulating film, lamp annealing, in other words, heat treatment is given to the semiconductor substrate SB at from 250 to 400° C. to form an insulating film ZM1 which is a reaction film formed by the reaction between the insulating film ZM2, an amorphous insulating film, and the semiconductor substrate SB made of silicon. This insulating film ZM1 is similar to the insulating film of First Embodiment and they are also similar in the advantage of forming an inversion layer IV in the semiconductor substrate SB by making use of interface states of the insulating film ZM1 and thereby reducing dark current noise of the CMOS image sensor.

The heat treatment is not only performed immediately after formation of the insulating film ZM2 but it may also be performed during from a shielding film SHF formation step to a microlens ML formation step to be performed later or after the microlens ML formation step. In consideration of the heat resistance of a color filter FL and a microlens ML each made of a resin, it is desired to perform the heat treatment prior to the steps of forming the color filter FL and the microlens ML.

Inventions made by the present inventors have been described specifically based on embodiments. It is needless to say that they are not limited to the embodiments but can be changed variously without departing from the gist of the inventions.

What is claimed is:

1. A semiconductor device comprising:
(a) a semiconductor substrate comprising silicon and having an element formation surface, a light receiving surface opposite to the element formation surface, a transfer transistor formed on the side of the element formation surface, a photodiode coupled in series with the transfer transistor, and a wiring formed over the element formation surface;
(b) a first amorphous insulating film formed over the light receiving surface, and
(c) an anti-reflective formed over the first amorphous insulating film,
wherein the semiconductor substrate and the first amorphous insulating film have therebetween a reaction film obtained by the reaction between the semiconductor substrate comprising silicon and the first amorphous insulating film.

2. The semiconductor device according to claim 1,
wherein the first amorphous insulating film comprises HfₓO_{y}, TaₓO_{y}, AlₓO_{y}, ZrₓO_{y}, or TiₓO_{y}.

3. The semiconductor device according to claim 2,
wherein the reaction film is a second amorphous insulating film and comprises Hf_{α}Si_{β}O_{χ}, Ta_{α}Si_{β}O_{χ}, Al_{α}Si_{β}O_{χ}, or Ti_{α}Si_{β}O_{χ}.

4. The semiconductor device according to claim 1,
wherein the anti-reflective film comprises a silicon oxide film.

5. The semiconductor device according to claim 1, further comprising, over the light receiving surface, a shielding film having a first opening corresponding to a formation region of the photodiode.

6. The semiconductor device according to claim 5,
wherein the shielding film comprises an aluminum film.

7. The semiconductor device according to claim 5, further comprising, over the shielding film, a protective film having a second opening corresponding to the formation region of the photodiode.

8. The semiconductor device according to claim 7, further comprising:
a color filter and a microlens in the second opening.

9. A method of manufacturing a semiconductor device, comprising the steps of:
(a) providing a semiconductor substrate having an element formation surface, a light receiving surface opposite to the element formation surface, a transfer transistor formed on the side of the element formation surface, a photodiode coupled in series with the transfer transistor, and a wiring formed over the element formation surface;
(b) forming a first amorphous insulating film over the light receiving surface of the semiconductor substrate; and
(c) forming an anti-reflective film over the first amorphous insulating film,
wherein the anti-reflective film is formed under film forming conditions of 400° C. or less.

10. The method of manufacturing a semiconductor device according to claim 9,
wherein the first amorphous insulating film is formed by PVD.

11. The method of manufacturing a semiconductor device according to claim 9,
wherein the anti-reflective film comprises a silicon oxide film and is formed by plasma CVD.

12. The method of manufacturing a semiconductor device according to claim 9,
wherein after completion of the step (c), the semiconductor substrate and the first amorphous insulating film have therebetween a reaction film obtained by the reaction between the semiconductor substrate and the first amorphous insulating film.

13. The method of manufacturing a semiconductor device according to claim 12,
wherein the first amorphous insulating film comprises HfₓO_{y}, TaₓO_{y}, AlₓO_{y}, ZrₓO_{y}, or TiₓO_{y}.

14. The semiconductor device according to claim 13,
wherein the semiconductor substrate comprises silicon and the reaction film is a second amorphous insulating film and comprises Hf_{α}Si_{β}O_{χ}, Ta_{α}Si_{β}O_{χ}, Al_{α}Si_{β}O_{χ}, or Ti_{α}Si_{β}O_{χ}.

15. The method of manufacturing a semiconductor device according to claim 9, further comprising the step of:
(d) forming a shielding film having a first opening corresponding to a formation region of the photodiode,
wherein the shielding film is formed under film forming conditions of 400° C. or less.

16. The method of manufacturing a semiconductor device according to claim 15,
wherein the shielding film comprises an aluminum film formed by PVD.

17. The method of manufacturing a semiconductor device according to claim 15, further comprising the step of:
(e) forming a protective film that covers the shielding film and has a second opening corresponding to the formation region of the photodiode,
wherein the protective film is formed under film forming conditions of 400° C. or less.

18. The method of manufacturing a semiconductor device according to claim 17,
wherein the protective film comprises a silicon nitride film and is formed by plasma CVD.

19. The method of manufacturing a semiconductor device according to claim 17, further comprising the step of:
(f) forming a color filter and a microlens in the second opening.

20. The method of manufacturing a semiconductor device according to claim 9,
wherein the transfer transistor has a gate electrode, a source region, and a drain region and the gate electrode is placed between the element formation surface and the wiring.
